(19) United States
(12) Patent Application Publication
(10) Pub. No.: US 2024/0079520 A1
(43) Pub. Date: Mar. 7, 2024

(54) LIGHT EMITTING DEVICE AND MANUFACTURING METHOD THEREOF

(71) Applicant: ENKRIS SEMICONDUCTOR, INC., Suzhou (CN)

(72) Inventors: Liyang ZHANG, Suzhou (CN); Kai CHENG, Suzhou (CN)

(73) Assignee: ENKRIS SEMICONDUCTOR, INC., Suzhou (CN)

(21) Appl. No.: 18/459,874

(22) Filed: Sep. 1, 2023

(30) Foreign Application Priority Data
Sep. 5, 2022 (CN) 202211078563.3

(51) Int. Cl. H01L 33/12; H01L 33/00; H01L 33/22; H01L 33/32

(52) U.S. Cl. CPC H01L 33/12; H01L 33/0075; H01L 33/22; H01L 33/32

(57) ABSTRACT

A light emitting device includes: a first substrate; a light emitting structure layer located on the first substrate; and an insertion layer located on the light emitting structure layer, a surface, away from the light emitting structure layer, of the insertion layer is a roughened surface, and the insertion layer has a protective effect on the light emitting structure layer. In the light emitting device provided by the present disclosure, the surface, away from the light emitting structure layer, of the insertion layer is the roughened surface, and the insertion layer has the protective effect on the light emitting structure layer during a peeling off process, which solves problems of reduced yield and reduced light extraction efficiency of a light emitting device.

### CROSS-REFERENCE TO RELATED APPLICATIONS

The present disclosure claims priority to Chinese Patent Application No. 202211078563.3, filed on Sep. 5, 2022, the entire content of which is incorporated herein by reference.

### TECHNICAL FIELD

The present disclosure relates to the field of semiconductor technologies, in particular to a light emitting device and a manufacturing method thereof.

### BACKGROUND

In recent years, light emitting diodes (Light-Emitting Diode, LED) have developed rapidly, and related research has continued to deepen, especially research on GaN-based materials.

At present, GaN-based LEDs, as a research hot spot of light emitting semiconductor devices, already have relatively mature manufacturing technologies. However, even with the relatively mature manufacturing technologies, it is easy to have problems such as reduced yield and reduced light extraction efficiency of a light emitting device.

### SUMMARY

In view of this, the present disclosure provides a light emitting device and a manufacturing method of the light emitting device, so as to solve problems of reduced yield and reduced light extraction efficiency of a light emitting device.

In a first aspect, an embodiment of the present disclosure provides a light emitting device, including: a first substrate; a light emitting structure layer, located on the first substrate; and an insertion layer, located on the light emitting structure layer, a surface, away from the light emitting structure layer, of the insertion layer is a roughened surface, and the insertion layer has a protective effect on the light emitting structure layer.

With reference to the first aspect, in some implementation manners of the first aspect, an orthographic projection, on the first substrate, of the insertion layer at least partially covers an orthographic projection, on the first substrate, of the light emitting structure layer.

With reference to the first aspect, in some implementation manners of the first aspect, a material of the insertion layer includes at least one of AlN or AlGaN.

With reference to the first aspect, in some implementation manners of the first aspect, the light emitting device further includes a second transition layer. The second transition layer is located between the light emitting structure layer and the insertion layer, and an orthographic projection, on the first substrate, of the second transition layer at least partially covers the orthographic projection, on the first substrate, of the light emitting structure layer.

With reference to the first aspect, in some implementation manners of the first aspect, a material of the second transition layer is at least one of GaN, AlGaN or AlInGaN.

With reference to the first aspect, in some implementation manners of the first aspect, a lattice constant of the second transition layer is between a lattice constant of the insertion layer and a lattice constant of the light emitting structure layer.

With reference to the first aspect, in some implementation manners of the first aspect, the light emitting device further includes a passivation layer located on the roughened surface of the insertion layer.

With reference to the first aspect, in some implementation manners of the first aspect, a refractive index of a material of the passivation layer is less than that of the insertion layer.

With reference to the first aspect, in some implementation manners of the first aspect, along a direction from the first substrate to the insertion layer, a size range of the insertion layer is greater than 0 nm, and less than or equal to 200 nm.

In a second aspect, an embodiment of the present disclosure provides a manufacturing method of the light emitting device, including: forming an epitaxial layer on a side of a growth substrate, the epitaxial layer including a first transition layer, an insertion layer and a light emitting structure layer which are sequentially epitaxially formed on the side of the growth substrate; bonding a first substrate on a side, away from the growth substrate, of the epitaxial layer; peeling off, by using a laser lift-off technique, the growth substrate until the first transition layer; and etching off, by using an etching technique, the first transition layer until the insertion layer, so that a surface, away from the light emitting structure layer, of the insertion layer is a roughened surface.

With reference to the second aspect, in some implementation manners of the second aspect, the manufacturing method further includes: performing surface treatment on the first transition layer formed after the growth substrate is peeled off, so as to remove remaining impurities after the growth substrate is peeled off.

With reference to the second aspect, in some implementation manners of the second aspect, the forming the epitaxial layer on a side of the growth substrate includes: beginning epitaxial growth of the first transition layer on a surface of the side of the growth substrate; stopping the epitaxial growth of the first transition layer before the first transition layer is converted from a three-dimensional rough structure to a two-dimensional flat structure, and beginning epitaxial growth of the insertion layer on the first transition layer, so as to make the surface, close to the first transition layer, of the insertion layer be a roughened surface; and epitaxially growing the light emitting structure layer on a surface, opposite to the roughened surface, of the insertion layer.

With reference to the second aspect, in some implementation manners of the second aspect, an orthographic projection, on the first substrate, of the insertion layer at least partially covers an orthographic projection, on the first substrate, of the light emitting structure layer.

With reference to the second aspect, in some implementation manners of the second aspect, the epitaxial layer further includes a second transition layer, the second transition layer is formed between the insertion layer and the light emitting structure layer, and an orthographic projection, on the first substrate, of the second transition layer at least partially covers the orthographic projection, on the first substrate, of the light emitting structure layer.

With reference to the second aspect, in some implementation manners of the second aspect, the first transition layer includes: a nucleation layer and a buffer layer formed on the nucleation layer, the nucleation layer being located between the buffer layer and the growth substrate. The peeling off, by using the laser lift-off technique, the growth substrate until the first transition layer includes: peeling off, by using the laser lift-off technique, the growth substrate and the nucleation layer, until the buffer layer.

In the light emitting device provided by the present disclosure, the surface, away from the light emitting structure layer, of the insertion layer is the roughened surface, which improves the light extraction efficiency. In addition, the insertion layer has the protective effect on the light emitting structure layer during a process of peeling off the growth substrate, which solves the problems of reduced yield and reduced light extraction efficiency of a light emitting device.

### BRIEF DESCRIPTION OF THE DRAWINGS

FIG. 1 is a schematic structural diagram of a light emitting device according to an embodiment of the present disclosure.

FIG. 2 is a schematic structural diagram of a light emitting device according to another embodiment of the present disclosure.

FIG. 3 is a schematic structural diagram of a light emitting device according to another embodiment of the present disclosure.

FIG. 4 is a schematic structural diagram of a light emitting device according to another embodiment of the present disclosure.

FIG. 5 is a schematic flowchart of a manufacturing method of a light emitting device according to an embodiment of the present disclosure.

FIG. 6a to FIG. 6d are schematic structural diagrams of an intermediate structure formed during a manufacturing process of a light emitting device according to an embodiment of the present disclosure.

FIG. 7 is a reflectance curve graph of an epitaxial structure during an epitaxial growth process according to an embodiment of the present disclosure.

FIG. 8 is a schematic structural diagram of an epitaxial layer of a light emitting device according to an embodiment of the present disclosure.

FIG. 9 is a schematic structural diagram of a first transition layer of a light emitting device according to an embodiment of the present disclosure.

### DETAILED DESCRIPTION OF THE EMBODIMENTS

The technical solutions in the embodiments of the present disclosure may be clearly and completely described below in combination with the accompanying drawings in the embodiments of the present disclosure. Obviously, the described embodiments are only some of the embodiments of the present disclosure, not all of them. In the description of the present disclosure, it should be noted that unless otherwise specified, “above” and “below” include the mentioned number; “multiple” and “several” mean two or more; the orientation or positional relationship indicated by the terms “upper”, “lower”, “left”, “right”, “inner”, “outer” etc. is only for the convenience of describing the present disclosure and simplifying the description, rather than indicating or implying that the referenced device or element must have a specific orientation, be constructed and operated in a specific orientation, so it should not be construed as a limitation of the present disclosure.

In recent years, light emitting diodes (Light Emitting Diode, LED) have been widely used in different industries due to their advantages of high brightness, low heat, and long life, such as advertising media, conferences and exhibitions, information release and other industries. Therefore, the light emitting diodes have been developed rapidly, and related research has been continuously increasing, especially, research on semiconductor devices made of GaN-based materials has gradually become extensive and in-depth.

At present, GaN-based LEDs, as a research hot spot of light emitting semiconductor devices, already have relatively mature preparation technologies, i.e., a substrate transfer technology. The substrate transfer technology is to transfer a GaN-based epitaxial structure grown on a substrate to a transfer substrate with better thermal and electrical conductivity by using a bonding technique and a laser lift-off technique, to form a flip LED chip. However, in a process of laser lift-off, it is usually inevitably to cause certain damage to the GaN-based epitaxial structure. When the GaN-based epitaxial structure is used to manufacture a light emitting device, problems of reduced yield and reduced light extraction efficiency of the light emitting device become more prominent.

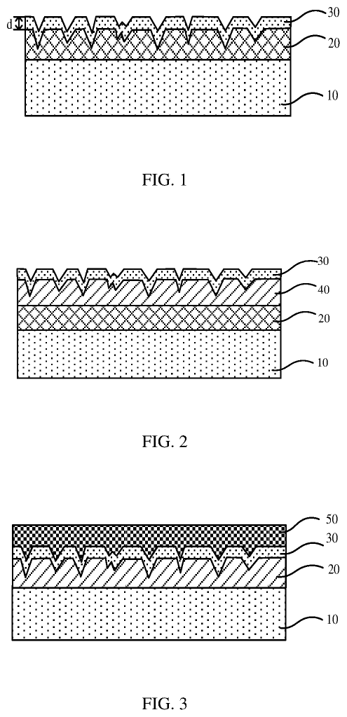

FIG. 1 is a schematic structural diagram of a light emitting device according to an embodiment of the present disclosure. As shown in FIG. 1, the light emitting device according to the embodiment of the present disclosure includes: a first substrate 10, a light emitting structure layer 20 and an insertion layer 30. The light emitting structure layer 20 is located on the first substrate 10. The insertion layer 30 is located on the light emitting structure layer 20, a surface, away from the light emitting structure layer 20, of the insertion layer 30 is a roughened surface, and the insertion layer 30 has a protective effect on the light emitting structure layer 20. Exemplarily, a surface, close to the light emitting structure layer 20, of the insertion layer 30 may be a roughened surface or a flat surface, and the surface, close to the light emitting structure layer, of the insertion layer is not specifically limited in the embodiments of the present disclosure.

In the light emitting device according to the embodiments of the present disclosure, disposal of the insertion layer with the roughened surface can improve light extraction efficiency. In addition, the insertion layer has the protective effect on the light emitting structure layer, which can avoid damage to the light emitting structure layer during a peeling off process of the growth substrate, improving yield of the light emitting device.

It should be noted that the light emitting structure layer 20 may include a p-type semiconductor layer, an n-type semiconductor layer, and an active layer located between the p-type semiconductor layer and the n-type semiconductor layer.

In an embodiment of the present disclosure, as shown in FIG. 1, an orthographic projection, on the first substrate 10, of the insertion layer 30 at least partially covers an orthographic projection, on the first substrate 10, of the light emitting structure layer 20. With such configuration, the insertion layer 30 has the protective effect the light emitting structure layer 20 during a process of laser lift-off.

In an embodiment of the present disclosure, a material of the insertion layer 30 may be at least one of AlN or AlGaN. It should be appreciated that the material of the insertion layer 30 may be selected according to actual requirements, and the material of the insertion layer 30 is not specifically limited in the embodiments of the present disclosure. Optionally, the material of the insertion layer 30 may be n-type AlGaN, which may serve as an n-type semiconductor layer of the light emitting structure layer 20.

In an embodiment of the present disclosure, as shown in FIG. 1, a range of a thickness d of the insertion layer 30 is greater than 0 nm, and less than or equal to 200 nm. It should be appreciated that the thickness of the insertion layer 30 can be selected in the range of greater than 0 nm, and less than or equal to 200 nm according to actual requirements, and the thickness of the insertion layer 30 is not specifically limited in the embodiments of the present disclosure. It should be noted that a direction of the thickness aligns with an arrangement direction of the first substrate 10, the light emitting structure layer 20 and the insertion layer 30.

In one example, the roughened surface, away from the light emitting structure layer 20, of the insertion layer 30 has protrusions and grooves. When the surface, close to the light emitting structure layer 20, of the insertion layer 30 is a flat surface, the thickness d of the insertion layer 30 refers to a distance from the protrusions of the roughened surface to the flat surface along a direction from the substrate 10 to the insertion layer 30; and when the surface, close to the light emitting structure layer 20, of the insertion layer 30 is also a roughened surface, this roughened surface also has protrusions and grooves, the thickness d of the insertion layer refers to a distance from the protrusions of the roughened surface, away from the light emitting structure layer 20, of the insertion layer 20, to the grooves of the roughened surface, close to the light emitting structure layer 20, of the insertion layer 20, along the direction from the first substrate 10 to the insertion layer 30.

FIG. 2 is a schematic structural diagram of a light emitting device according to another embodiment of the present disclosure. The embodiment shown in FIG. 2 is on the basis of the embodiments shown in FIG. 1. The difference between the embodiment shown in FIG. 2 and the embodiments shown in FIG. 1 may be mainly described below, and the similarities may not be repeated here.

As shown in FIG. 2, the light emitting device according to the embodiment of the present disclosure further includes a second transition layer 40, and the second transition layer 40 is located between the light emitting structure layer 20 and the insertion layer 30. An orthographic projection, on the first substrate 10, of the second transition layer 40 at least partially covers an orthographic projection, on the first substrate 10, of the light emitting structure layer 20.

In an embodiment of the present disclosure, a material of the second transition layer 40 may be selected according to actual requirements. For example, the material of the second transition layer is at least one of GaN, AlGaN or AlInGaN. The material of the second transition layer 40 is not specifically limited in the embodiments of the present disclosure.

In the light emitting device according to the embodiments of the present disclosure, the second transition layer is provided between the light emitting structure layer and the insertion layer, and the orthographic projection, on the first substrate, of the second transition layer at least partially covers the orthographic projection, on the first substrate, of the light emitting structure layer. Such a configuration can further protect the light emitting structure layer and avoid damage to the light emitting structure layer during a peeling off process, thereby improving yield of the light emitting device. Optionally, a lattice constant of the second transition layer is between a lattice constant of the insertion layer and a lattice constant of the light emitting structure layer, which is conducive to growing high quality epitaxial crystals, thus improving yield of the light emitting device.

FIG. 3 is a schematic structural diagram of a light emitting device according to another embodiment of the present disclosure. The embodiment shown in FIG. 3 is on the basis of the embodiments shown in FIG. 1. The difference between the embodiment shown in FIG. 3 and the embodiments shown in FIG. 1 may be mainly described below, and the similarities may not be repeated here.

As shown in FIG. 3, the light emitting device according to the embodiment of the present disclosure further includes a passivation layer 50. The passivation layer 50 is located on the roughened surface of the insertion layer 30. The passivation layer 50 may be utilized to protect an internal structure of the light emitting device.

In an embodiment of the present disclosure, a material of the passivation layer 50 may be selected according to actual requirements, for example, materials such as SO₂, Al₂O₃, or SiON. The material of the passivation layer 50 is not specifically limited in the embodiments of the present disclosure. Optionally, a refractive index may be considered when the material of the passivation layer 50 is selected. The refractive index of the material of the passivation layer 50 is less than that of the insertion layer 30, which can further increase a light extraction rate, thereby improving light extraction efficiency.

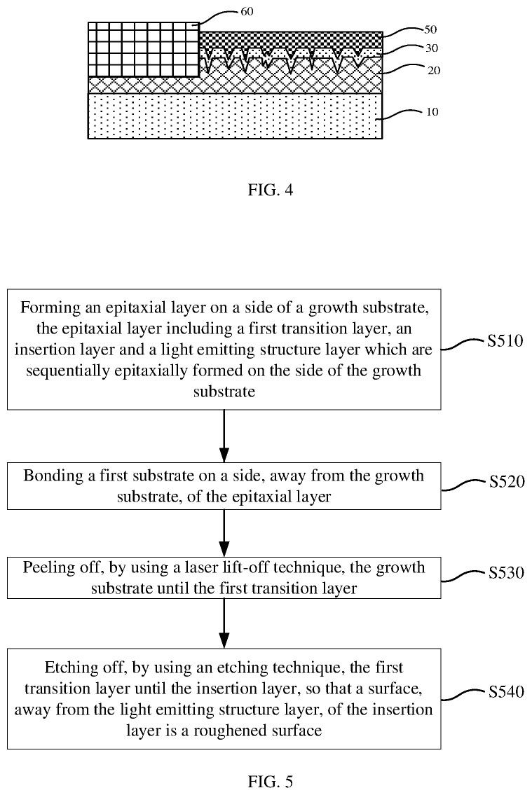

FIG. 4 is a schematic structural diagram of a light emitting device according to another embodiment of the present disclosure. The embodiment shown in FIG. 4 is on the basis of the embodiments shown in FIG. 3. The difference between the embodiment shown in FIG. 4 and the embodiments shown in FIG. 3 may be mainly described below, and the similarities may not be repeated here.

As shown in FIG. 4, the light emitting device according to the embodiment of the present disclosure further includes an electrode 60, and the electrode 60 electrically connected to the light emitting structure layer 20 for providing electrical signals to the light emitting structure layer 20.

FIG. 5 is a schematic flowchart of a manufacturing method of a light emitting device according to an embodiment of the present disclosure. As shown in FIG. 5, the manufacturing method of the light emitting device according to the embodiment of the present disclosure includes the following steps.

Step S510, forming an epitaxial layer on a side of a growth substrate, the epitaxial layer including a first transition layer, an insertion layer and a light emitting structure layer which are sequentially epitaxially formed on the side of the growth substrate.

It should be noted that an epitaxial growth process of the first transition layer includes a conversion process from 3D to 2D. The conversion process from 3D to 2D may be understood as a process of converting from a roughened structure to a flat structure. Before the first transition layer is not converted to 2D, epitaxial growth of the first transition layer is stopped, and epitaxial growth of the insertion layer is started, so that a surface, close to the first transition layer, of the insertion layer is a roughened surface, that is, a surface, away from the light emitting structure layer, of the insertion layer is the roughened surface.

Exemplarily, the epitaxial growth process may be Atomic Layer Deposition (Atomic Layer Deposition, ALD), Chemical Vapor Deposition (Chemical Vapor Deposition, CVD), Molecular Beam Epitaxy (Molecular Beam Epitaxy, MBE), Plasma Enhanced Chemical Vapor Deposition (Plasma Enhanced Chemical Vapor Deposition, PECVD), Low Pressure Chemical Vapor Deposition (Low Pressure Chemical Vapor Deposition, LPCVD), Metal-Organic Chemical Vapor Deposition (Mental-Organic Chemical Vapor Deposition, MOCVD) or a combination thereof, etc., and the epitaxial growth process is not specifically limited in the embodiments of the present disclosure.

Exemplarily, a material of the growth substrate may be sapphire, silicon carbide, lithium niobate, or diamond, etc. It should be appreciated that the material of the growth substrate may be selected according to requirements, and the material of the growth substrate is not specifically limited in the embodiments of the present disclosure.

Step S520, bonding a first substrate on a side, away from the growth substrate, of the epitaxial layer.

Exemplarily, a material of the first substrate may be selected according to actual requirements. For example, the material of the first substrate may be Si crystal, SiC crystal, ceramic substrate, sapphire crystal, glass material or AlSi crystal, or the material of the first substrate may also be InP, GaAs, or GaN, or the first substrate may also be a flexible substrate, and a material of the flexible substrate is not limited to PET or PDMS, and the material of the first substrate is not specifically limited in the embodiments of the present disclosure.

Step S530, peeling off, by using a laser lift-off technique, the growth substrate until the first transition layer.

Exemplarily, the growth substrate and the epitaxial layer are peeled off by using a laser lift-off method, and a peeling off stop position is in the first transition layer.

Step S540, etching off, by using an etching technique, the first transition layer until the insertion layer, so that a surface, away from the light emitting structure layer, of the insertion layer is a roughened surface.

It should be noted that, after the first transition layer is etched off, an exposed surface of the insertion layer is the roughened surface formed when the first transition layer is suspended from 3D to 2D.

Exemplarily, dry etching is selectively performed on the first transition layer. A method for determining timing of stopping etching during a process of etching off the first transition layer until the insertion layer may be that during etching, when an element (such as a Al element) contained in the insertion layer is detected, the etching is stopped; or may be that positioning is performed according to an actual position of the insertion layer, and the etching is stopped when positioning coordinates are reached. It should be appreciated that, in the process of etching off the first transition layer, how to stop the etching until the insertion layer may be selected according to requirements.

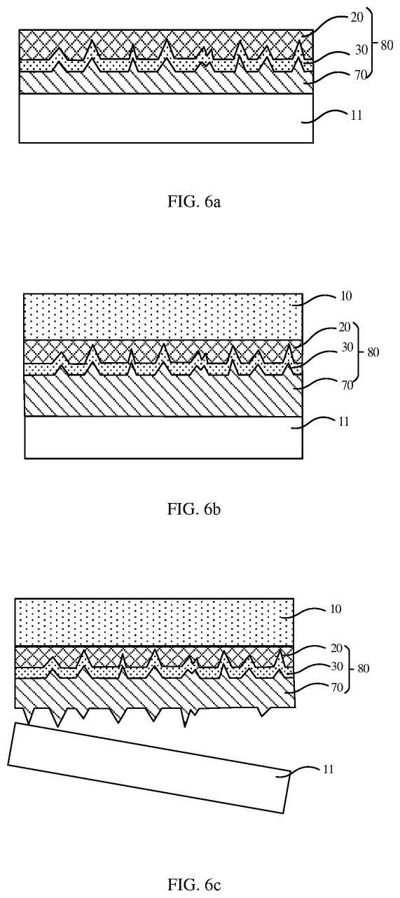

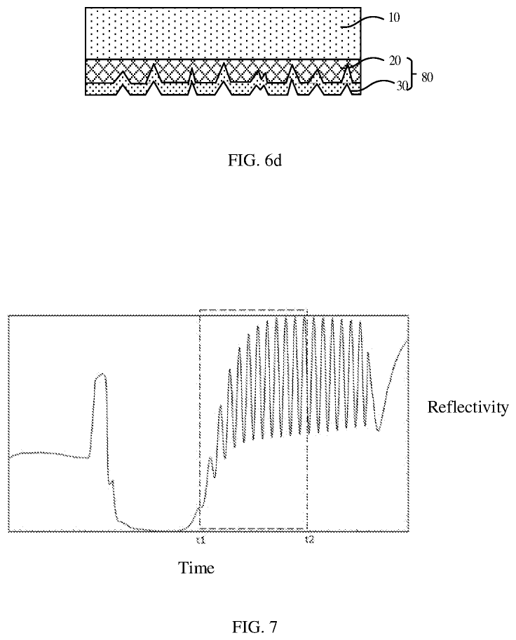

The manufacturing method of the light emitting device shown in FIG. 6 may be described in detail below with a specific embodiment.

FIG. 6a to FIG. 6d are schematic structural diagrams of an intermediate structure formed during a manufacturing process of a light emitting device according to an embodiment of the present disclosure. It may be seen from FIG. 6a to FIG. 6d that the manufacturing process of the light emitting device is as follows.

As shown in FIG. 6a, an epitaxial layer 80 is formed on a side of a growth substrate 11, and the epitaxial layer 80 includes a first transition layer 70, an insertion layer 30 and a light emitting structure layer 20 which are sequentially epitaxially formed on the side of the growth substrate 11.

Exemplarily, a material of the insertion layer includes at least one of AlN or AlGaN. It should be appreciated that the material of the insertion layer 30 may be selected according to requirements, and the material of the insertion layer is not specifically limited in the embodiments of the present disclosure.

As shown in FIG. 6b, the first substrate 10 is bonded on a side, away from the growth substrate 11, of the epitaxial layer 80.

Exemplarily, a bonding medium layer (not shown in the figures) may be formed between the epitaxial layer 80 and the first substrate 10, and after the growth substrate 11 is peeled off, the epitaxial layer 80 is transferred to the first substrate 10. Disposal of the bonding medium layer can improve a bonding capability between the epitaxial layer 80 and the first substrate 10.

Exemplarily, a material of the first substrate 10 may be selected according to actual requirements. For example, the material of the first substrate 10 may be Si crystal, SiC crystal, ceramic substrate, sapphire crystal, glass material or AlSi crystal, or the material of the first substrate 10 may be InP, GaAs or GaN, or the first substrate 10 may be a flexible substrate, and a material of the flexible substrate is not limited to PET or PDMS, and the material of the first substrate is not specifically limited in the embodiments of the present disclosure.

Exemplarily, a material of the bonding medium layer may be selected according to actual requirements. For example, the material of the bonding medium layer may be any elemental metal or an alloy of at least two elemental metals of molybdenum (Mo), gold (Au), titanium (Ti), copper (Cu), palladium (Pd), platinum (Pt), tungsten (W), nickel (Ni) or chromium (Cr); or the material of the bonding medium layer is a conductive polymer composed of resin matrix and at least one conductive particle such as silver (Ag), gold (Au), copper (Cu), aluminum (Al), zinc (Zn), iron (Fe), nickel (Ni) or graphite (C); or the material of the bonding medium layer is a conductive paste composed of at least one particle of conductive particle, such as silver (Ag), gold (Au), Copper (Cu), Aluminum (Al), Zinc (Zn), Iron (Fe), Nickel (Ni) or Graphite (C), and at least one of binders, solvents, or additives; or the material of the bonding medium layer is silicate-based high-temperature conductive adhesive; or the material of the bonding medium layer is superalloy paste made of metals such as nickel (Ni), chromium (Cr), silicon (Si) or boron (B). The material of the bonding medium layer is not specifically limited in the embodiments of the present disclosure.

As shown in FIG. 6c, the growth substrate 11 is peeled off by using laser lift-off, and a peeling off stop position is in the first transition layer 70.

Exemplarily, the growth substrate 11 is peeled off from the epitaxial layer 80 by using the laser lift-off. During the manufacturing process of the light emitting device structure, peeling off the growth substrate 11 may cause certain damage to the epitaxial layer 80, especially to the light emitting structure layer 20 in the epitaxial layer 80. Therefore, in the embodiment of the present disclosure, disposal of the insertion layer 30 can protect the light emitting structure layer 20.

As shown in FIG. 6d, the first transition layer 70 is etched off until the insertion layer 30, so that a surface, away from the light emitting structure layer 20, of the insertion layer 30 is a roughened surface.

Exemplarily, after the growth substrate 11 is peeled off, a roughened surface may be formed on a side, close to the growth substrate 11, of the first transition layer 70. Etching is started from the roughened surface formed by the first transition layer 70, and until reaching the insertion layer 30, the etching is stopped, so as to make the surface, away from the light emitting structure layer 20, of the insertion layer 30 become the roughened surface.

FIG. 7 is a reflectance curve graph of an epitaxial structure during an epitaxial growth process according to an embodiment of the present disclosure. As shown in FIG. 7, the dotted box refers to a time period from time t1 to time t2, and from the time t1 to the time t2, a reflectivity of the epitaxial structure shows a change pattern of initially increasing and eventually leveling off, that is to say, the epitaxial structure is changed from a three-dimensional (3D) roughened structure to a two-dimensional (2D) flat surface. With reference to FIG. 6a, at any time point before the time t2, an epitaxial surface of the first transition layer 70 is the three-dimensional roughened structure, so at any time point before the time t2, the insertion layer 30 is started to manufacture epitaxially, so that the surface, close to the first transition layer 70, of the insertion layer 30 presents a three-dimensional roughened topography, and therefore, the insertion layer 30 has the roughened surface.

In the embodiment of the present disclosure, a process of converting the first transition layer from 3D to 2D is suspended, and the insertion layer is started to grow epitaxially, so as to form the roughened surface on the surface, away from the light emitting structure layer, of the insertion layer. After dry etching is performed on the first transition layer, the roughened surface is retained in the insertion layer. Such a configuration can simplify the manufacturing process of the light emitting device, and protect the light emitting structure layer from influence of the laser lift-off, and further improve light extraction efficiency of the light emitting device.

In an embodiment of the present disclosure, after the growth substrate is peeled off by using the laser lift-off, the manufacturing method further includes performing surface treatment on the first transition layer located at the peeling off stop position, so as to remove residual impurities after the peeling off. Exemplarily, a method of performing the surface treatment on the first transition layer located at the peeling off stop position may be selected according to actual requirements. For example, a hydrochloric acid immersion method or an atmospheric corrosion method may be used to treat a surface of the first transition layer located at the peeling off stop position. The method of performing the surface treatment on the first transition layer located at the peeling off stop position is not specifically limited in the embodiments of the present disclosure. After the growth substrate is peeled off by using the laser lift-off, some impurities, such as Ga droplet residues, usually remain on the surface of the first transition layer, and the remaining impurities can be removed by performing the surface treatment on the first transition layer located at the peeling off stop position.

FIG. 8 is a schematic structural diagram of an epitaxial layer of a light emitting device according to an embodiment of the present disclosure. As shown in FIG. 8, in the embodiment of the present disclosure, the epitaxial layer 80 further includes a second transition layer 40. The second transition layer 40 is formed between the insertion layer 30 and the light emitting structure layer 20, and an orthographic projection, on the growth substrate 11, of the second transition layer 40 at least partially covers an orthographic projection, on the growth substrate 11, of the light emitting structure layer 20.

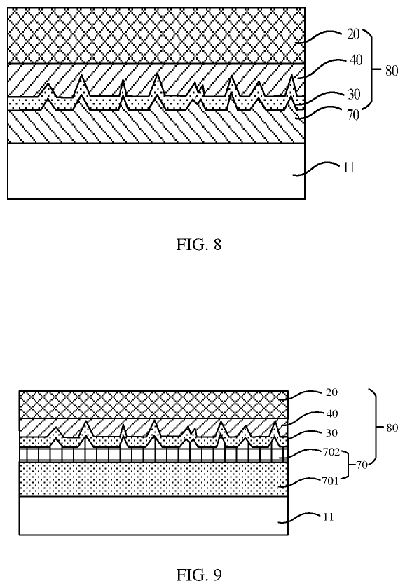

FIG. 9 is a schematic structural diagram of a first transition layer of a light emitting device according to an embodiment of the present disclosure. The embodiment shown in FIG. 9 is on the basis of the embodiments shown in FIG. 8. The difference between the embodiment shown in FIG. 9 and the embodiments shown in FIG. 8 may be mainly described below, and the similarities may not be repeated.

As shown in FIG. 9, the first transition layer 70 includes a nucleation layer 701 and a buffer layer 702 formed on the nucleation layer 701. The nucleation layer 701 is located between the buffer layer 702 and the growth substrate 11.

Exemplarily, when the growth substrate 11 is peeled off, an actual peeling off stop position is located in the buffer layer 702. For example, when the growth substrate 11 is peeled off by using the laser lift-off, the peeling off stop position is located in the buffer layer 702, and during a process of peeling off the growth substrate 11 by using the laser lift-off, the growth substrate 11 and the nucleation layer 701 may selectively be peeled off together.

Exemplarily, a material of the nucleation layer 701 may be selected according to actual requirements. For example, the material of the nucleation layer 701 may be at least one of GaN, AlN or AlGaN. Exemplarily, the nucleation layer 701 made of the GaN and AlN is obtained by Low Temperature (Low Temperature, LT) epitaxial growth or Physical Vapor Deposition (Physical Vapor Deposition, PVD). The material of the nucleation layer is not specifically limited in the embodiments of the present disclosure.

Exemplarily, a material of the buffer layer 702 may be selected according to actual requirements. For example, the material of the buffer layer 702 may be at least one of GaN, AlGaN or AlInGaN, and the material of the buffer layer is not specifically limited in the embodiments of the present disclosure.

In the embodiment of the present disclosure, disposal of the nucleation layer can reduce a dislocation density and a defect density during an epitaxial growth process, and further improve crystal quality; and disposal of the buffer layer can buffer a stress in the epitaxial layer above the growth substrate, so as to avoid cracking of the epitaxial layer and enhance stability.

The above are only specific embodiments of the present disclosure, but the protection scope of the present disclosure is not limited thereto. Any person familiar with the technical field may easily think of various equivalent modifications or replacements within the technical scope of the present disclosure. These modifications or replacements should be covered within the protection scope of the present disclosure. Therefore, the protection scope of the present disclosure should be determined by the protection scope of the claims.

What is claimed is:

1. A light emitting device, comprising:
a first substrate;
a light emitting structure layer, located on the first substrate; and
an insertion layer, located on the light emitting structure layer, wherein, a surface, away from the light emitting structure layer, of the insertion layer is a roughened surface, and the insertion layer has a protective effect on the light emitting structure layer.

2. The light emitting device according to claim 1, wherein an orthographic projection, on the first substrate, of the insertion layer at least partially covers an orthographic projection, on the first substrate, of the light emitting structure layer.

3. The light emitting device according to claim 1, wherein a material of the insertion layer comprises at least one of AlN or AlGaN.

4. The light emitting device according to claim 1, further comprising:
a second transition layer, located between the light emitting structure layer and the insertion layer, wherein an orthographic projection, on the first substrate, of the second transition layer at least partially covers the orthographic projection, on the first substrate, of the light emitting structure layer.

5. The light emitting device according to claim 4, wherein a material of the second transition layer is at least one of GaN, AlGaN or AlInGaN.

6. The light emitting device according to claim 4, wherein a lattice constant of the second transition layer is between a lattice constant of the insertion layer and a lattice constant of the light emitting structure layer.

7. The light emitting device according to claim 1, further comprising:
a passivation layer, located on the roughened surface of the insertion layer.

8. The light emitting device according to claim 7, wherein a refractive index of a material of the passivation layer is less than that of the insertion layer.

9. The light emitting device according to claim 1, wherein along a direction from the first substrate to the insertion layer, a size range of the insertion layer is greater than 0 nm, and less than or equal to 200 nm.

10. A manufacturing method of a light emitting device, comprising:
forming an epitaxial layer on a side of a growth substrate, the epitaxial layer comprising a first transition layer, an insertion layer and a light emitting structure layer which are sequentially epitaxially formed on the side of the growth substrate;
bonding a first substrate on a side, away from the growth substrate, of the epitaxial layer;
peeling off, by using a laser lift-off technique, the growth substrate until the first transition layer; and
etching off, by using an etching technique, the first transition layer until the insertion layer, so that a surface, away from the light emitting structure layer, of the insertion layer is a roughened surface.

11. The manufacturing method according to claim 10, further comprising:
performing surface treatment on the first transition layer formed after the growth substrate is peeled off, so as to remove remaining impurities after the growth substrate is peeled off.

12. The manufacturing method according to claim 10, wherein the forming the epitaxial layer on a side of the growth substrate comprises:
beginning epitaxial growth of the first transition layer on a surface of the side of the growth substrate;
stopping the epitaxial growth of the first transition layer before the first transition layer is converted from a three-dimensional rough structure to a two-dimensional flat structure, and beginning epitaxial growth of the insertion layer on the first transition layer, so as to make a surface, close to the first transition layer, of the insertion layer be a roughened surface; and
epitaxially growing the light emitting structure layer on a surface, opposite to the roughened surface, of the insertion layer.

13. The manufacturing method according to claim 10, wherein an orthographic projection, on the first substrate, of the insertion layer at least partially covers an orthographic projection, on the first substrate, of the light emitting structure layer.

14. The manufacturing method according to claim 10, wherein the epitaxial layer further comprises a second transition layer, the second transition layer is formed between the insertion layer and the light emitting structure layer, and an orthographic projection, on the first substrate, of the second transition layer at least partially covers an orthographic projection, on the first substrate, of the light emitting structure layer.

15. The manufacturing method according to claim 10, wherein the first transition layer comprises:
a nucleation layer, and
a buffer layer formed on the nucleation layer, the nucleation layer being located between the buffer layer and the growth substrate,
wherein the peeling off, by using a laser lift-off technique, the growth substrate until the first transition layer comprises:
peeling off, by using the laser lift-off technique, the growth substrate and the nucleation layer, until the buffer layer.
